(19) United States
(12) Patent Application Publication
(10) Pub. No.: US 2012/0112607 A1
(43) Pub. Date: May 10, 2012

(54) CERAMIC COMPOSITION FOR PIEZOELECTRIC ACTUATOR AND PIEZOELECTRIC ACTUATOR INCLUDING THE SAME

(75) Inventors: Boum Seock KIM, Suwon (KR); Seung Gyo JEONG, Hwaseong (KR); Eun Tae PARK, Yongin (KR)

(73) Assignees: KOREAN UNIVERSITY RESEARCH & BUSINESS FOUNDATION; SAMSUNG ELECTRO-MECHANICS CO.,LTD.

(21) Appl. No.: 13/191,006

(22) Filed: Jul. 26, 2011

(30) Foreign Application Priority Data
Nov. 10, 2010 (KR) 10-2010-0111744

(51) Int. Cl. H01L 41/187; H01L 41/047; H01L 41/22; C04B 35/626

(52) U.S. Cl. 310/363; 252/62.9 PZ; 29/25.35

(57) ABSTRACT

Disclosed are a ceramic composition for a piezoelectric actuator and a piezoelectric actuator including the same. The ceramic composition for a piezoelectric actuator includes piezoelectric ceramic powder expressed by a chemical formula, (1−x)Pb(Zr_{(1-y)}Ti_{y})O₃-xPb(Ni_{1/3}Nb_{2/3})O₃, where, x ranges from 0.25 to 0.4, and y ranges from 0.4 to 0.7. The ceramic composition for a piezoelectric actuator permits low-temperature firing while implementing superior piezoelectric properties.

### CROSS-REFERENCE TO RELATED APPLICATIONS

This application claims the priority of Korean Patent Application No. 10-2010-111744 filed on Nov. 10, 2010, in the Korean Intellectual Property Office, the disclosure of which is incorporated herein by reference.

### BACKGROUND OF THE INVENTION

1. Field of the Invention

The present invention relates to a ceramic composition for a piezoelectric actuator and a piezoelectric actuator including the same, and more particularly, to a ceramic composition for a piezoelectric actuator, capable of achieving enhanced piezoelectric properties and permitting low-temperature firing, and a piezoelectric actuator including the same.

2. Description of the Related Art

The recent development of the precision machining industry and information industry has led to the widespread application of piezoelectric actuators for controlling micro-displacement and vibration, to precision optical devices, semiconductor equipment, gas flow control pumps, valves or the like. This is because the piezoelectric actuators enable miniaturization, have precise control and have high response rates, as compared to related art mechanical driving devices.

With the development of mechatronics, micro-displacement control components have been switched over from typical step motors to piezoelectric actuators. Accordingly, a material generating high displacement is required for the application of piezoelectric actuators using piezoelectric ceramics.

An actuator, which is in current use, utilizes relaxer ferroelectric materials containing PZT (Pb(ZrTi)O₃) or Pb. These materials, when in the form of a disc, have limitations in actual application, since a sample displacement of less than 1% occurs.

To solve the aforementioned limitations, various types of actuators, such as cantilever, flextensional and multilayer actuators have been developed.

As for multilayer actuators, considering that PZT in the form of a disc is deformed at high voltages, each layer is made to be thin to lower operating voltages, and electrodes are provided in parallel in each disc to thereby generate large electric fields even at low voltages. To manufacture such multilayer actuators, a cutting and bonding method for simple multilayer actuators, and a co-sintering method in the case of a tape-casting and printing method may be used.

In the cutting and bonding method, thinned piezoelectric PZT is bonded with copper foil by using a silver epoxy. Since the piezoelectric material is processed to have a thickness of between 0.3 mm and 1 mm and bonded, manufacturing processes are simplified; however, a relatively high operating voltage is required.

In the tape-casting and printing method, PZT and polymer are mixed together and made into thin tapes, electrode materials such as Pd or the like are then printed thereon, and a plurality of resultant layers are bonded together. Thereafter, the polymer is burnt and thus removed, and co-sintering is performed thereupon. In this case, the tape-casting process of making the ceramic-polymer complex into thin-tape like structures is complicated, and the printing process is difficult to perform, thereby resulting in high manufacturing costs. However, this tape-casting and printing method is advantageous in that very thin layers can be produced.

Meanwhile, when the sintering is performed at high temperature of approximately 1200□ by using a High-Temperature Co-firing Ceramic (HTCC) process, costly rare-earth metals (mainly, Pt, Pd or the like) are inevitably used. This is because only rare-earth metals such as Pt, Pd or the like can bear high temperature heat while having high conductivity.

Therefore, if the sintering temperature is lowered to thereby render relatively economical metals, such as silver, copper or aluminum, adequate for use in electrodes, manufacturing costs can be significantly lowered.

### SUMMARY OF THE INVENTION

An aspect of the present invention provides a ceramic composition for a piezoelectric actuator, which possesses superior piezoelectric properties and permits low-temperature firing, and a piezoelectric actuator including the same.

According to an aspect of the present invention, there is provided a ceramic composition for a piezoelectric actuator, the ceramic composition, including piezoelectric ceramic powder expressed by a chemical formula, (1−x)Pb(Zr_{(1-y)}Ti_{y})O₃-xPb(Ni_{1/3}Nb_{2/3})O₃, where, x ranges from 0.25 to 0.4, and y ranges from 0.4 to 0.7.

The ceramic composition may further include at least one additive selected from the group consisting of ZnO and CuO.

The additive may be added in an amount of from 0.5 mol % to 10 mol %.

According to another aspect of the present invention, there is provided a a method of manufacturing a ceramic composition for a piezoelectric actuator, the method including: preparing a ceramic mixture by weighing raw powder so as to have a composition of (1−x)Pb(Zr_{(1-y)}Ti_{y})O₃-xPb(Ni_{1/3}Nb_{2/3})O₃, where x ranges from 0.25 to 0.4, and y ranges from 0.4 to 0.7; and calcining the ceramic mixture to produce piezoelectric ceramic powder having the composition of (1−x)Pb(Zr_{(1-y)}Ti_{y})O₃-xPb(Ni_{1/3}Nb_{2/3})O₃, where x ranges from 0.25 to 0.4, and y ranges from 0.4 to 0.7.

The raw powder may include PbO, ZrO, TiO₂, NiO and Nb₂O₅.

The method may further include mixing at least one additive selected from the group consisting of ZnO and CuO after the producing of the piezoelectric ceramic powder.

The additive may be added in an amount of from 0.5 mol % to 10 mol %.

According to another aspect of the present invention, there is provided a piezoelectric actuator including: at least one piezoelectric layer including a ceramic composition including piezoelectric ceramic powder having a composition of (1−x)Pb(Zr_{(1-y)}Ti_{y})O₃-xPb(Ni_{1/3}Nb_{2/3})O₃, where x 0.25 to 0.4, and y ranges from 0.4 to 0.7; and an electrode layer formed on at least one of top and bottom surfaces of the piezoelectric layer.

The piezoelectric layer may include at least one additive selected from the group consisting of ZnO and CuO.

The electrode layer may include at least one metal selected from the group consisting of silver, copper and aluminum.

According to another aspect of the present invention, there is provided a method of manufacturing a piezoelectric actuator, the method including: preparing a ceramic mixture by weighing raw powder so as to have a composition of (1−x)Pb(Zr_{(1-y)}Ti_{y})O₃-xPb(Ni_{1/3}Nb_{2/3})O₃, where x ranges from 0.25 to 0.4, and y ranges from 0.4 to 0.7; calcining the ceramic mixture to produce piezoelectric ceramic powder having a composition of (1−x)Pb(Zr_{(1-y)}Ti_{y})O₃-xPb(Ni_{1/3}Nb_{2/3})O₃, where x ranges from 0.25 to 0.4, and y ranges from 0.4 to 0.7; forming a piezoelectric layer using a ceramic composition including the piezoelectric ceramic powder; forming a stack by forming an electrode layer on at least one of top and bottom surfaces of the piezoelectric layer; and firing the stack at a temperature of 950° C. or less.

The raw powder may include PbO, ZrO, TiO₂, NiO and Nb₂O₅.

The ceramic composition may be mixed with at least one additive selected from the group consisting of ZnO and CuO.

The electrode layer may be formed of at least one metal selected from the group consisting of silver, copper and aluminum.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic cross-sectional view illustrating a piezoelectric actuator according to an exemplary embodiment of the present invention; and

FIG. 2 is a graph showing piezoelectric properties of a sample manufactured according to an exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

A ceramic composition for a piezoelectric actuator, according to an exemplary embodiment of the invention includes PZT-PNN piezoelectric ceramic powder.

In more detail, the PZT-PNN piezoelectric ceramic powder is expressed by a chemical formula, (1−x)Pb(Zr_{(1-y)}Tiy)O₃-xPb(Ni_{1/3}Nb_{2/3})O₃, where, x ranges from 0.25 to 0.4, and y ranges from 0.4 to 0.7.

As for the piezoelectric ceramic powder according to this exemplary embodiment of the invention, Pb(Ni_{1/3}Nb_{2/3})O₃ (i.e., PNN) is added to Pb(ZrTi)O₃ (i.e., PZT). The addition of a small amount of PNN to the PZT enhances the piezoelectric properties of the PZT.

In the above chemical formula, ‘x’, representing the amount of PNN being added, may range from 0.25 to 0.4. If the PNN is added in an excessive amount, the piezoelectric properties may be lost.

In the PZT, ‘y’, representing a ratio of Ti to Zr may range from 0.4 to 0.7. The PZT-PNN piezoelectric ceramic powder may acquire excellent piezoelectric properties upon controlling the ratio of Ti to Zr.

The ceramic composition for a piezoelectric actuator according to this exemplary embodiment of the invention may include at least one additive selected between ZnO and CuO. The additive may be added in an amount of from 0.5 mol % to 10 mol %.

The ceramic composition for a piezoelectric actuator according to this exemplary embodiment of the invention may include one or both of ZnO and CuO as an additive. In the case in which both ZnO and CuO are used, ZnO and CuO are added in amounts of 5 mol % and 5 mol %, respectively.

The addition of such additives may enhance the piezoelectric properties of the ceramic composition for a piezoelectric actuator.

The PZT-PNN pizoelectric ceramic powder according to this exemplary embodiment of the invention may be manufactured by mixing and calcining raw powder of PbO, ZrO₂, TiO₂, NiO, and Nb₂O₅.

The raw powder may be mixed such that the PZT-PNN piezoelectric ceramic powder has a composition of (1−x)Pb(Zr_{(1-y)}Ti_{y})O₃-xPb(Ni_{1/3}Nb_{2/3})O₃, after the calcinations, where, x ranges from 0.25 to 0.4, and y ranges from 0.4 to 0.7.

Through the mixing and calcining of the raw powder, PZT-PNN, which is perovskite powder having a stable ABO₃ structure, may be produced.

The calcination may be performed at a temperature of between 800° C. and 1000° C. for two to five hours.

Furthermore, the ceramic composition for a piezoelectric actuator, according to this exemplary embodiment of the invention, may include at least one of ZnO and CuO as an additive. However, the present invention is not limited thereto.

Powder of ZnO and CuO may be added in the range of 0.5 mol % to 10 mol %. The ZnO and CuO powder is mixed with PNT-PNN, the piezoelectric ceramic powder through a milling process or the like, thereby manufacturing the ceramic composition for a piezoelectric ceramic composition.

In general, electrodes and piezoelectric materials need to be configured in layers in order to implement a multilayer piezoelectric actuator. Accordingly, the electrode and the piezoelectric materials need to maintain a stable interface therebetween and be subjected to co-firing in the process.

For the co-firing, the electrodes are required to have a higher melting point than the firing temperature of the piezoelectric material.

A piezoelectric material used for an existing multilayer piezoelectric actuator is mainly a PZT-based material, and has a relatively high firing temperature ranging from 1100° C. to 1250° C. Thus, an electrode material capable of maintaining its properties at this firing temperature needs to be used between stacked PZT piezoelectric layers.

For this reason, an electrode material containing a large amount of Pd, which is relatively expensive, has typically been used.

The more Pd that is used, the higher the price of a piezoelectric actuator becomes. Therefore, research into adding a new composition to a PZT-based material to thereby lower the firing temperature while maintaining appropriate piezoelectric properties is being continuously conducted.

If the firing temperature of the piezoelectric material is lowered, a low-temperature electrode material containing a small amount of Pd becomes available for a piezoelectric actuator, thereby contributing to a significant reduction in manufacturing costs.

The ceramic composition for a piezoelectric actuator according to this exemplary embodiment of the present invention is sinterable at a low temperature of 950° C. or lower, thereby allowing for the use of a low-temperature material containing Pd in small amount.

According to another exemplary embodiment of the invention, a piezoelectric actuator including the above-described ceramic composition for a piezoelectric actuator is provided.

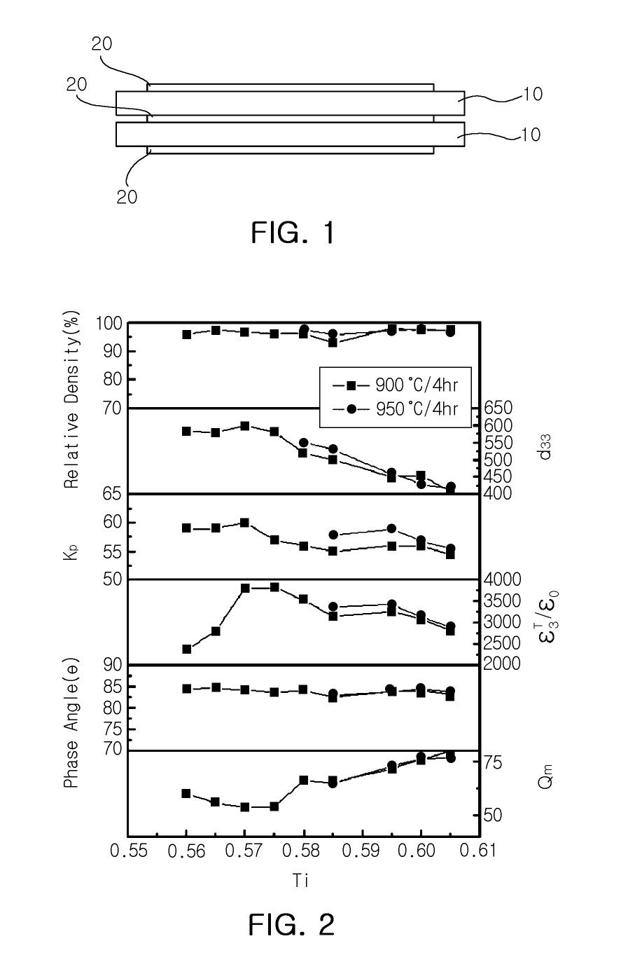

FIG. 1 is a schematic cross-sectional view illustrating a piezoelectric actuator according to an exemplary embodiment of the present invention.

Referring to FIG. 1, the piezoelectric actuator, according to an exemplary embodiment of the present invention, includes a piezoelectric layer 10 and an electrode layer 20 formed on at least one of the top and bottom surfaces of the piezoelectric layer 10.

The piezoelectric layer 10 may be formed as one or more piezoelectric layers, and include the ceramic composition for a piezoelectric actuator according to the previous exemplary embodiment of the present invention.

As described above, the ceramic composition for a piezoelectric actuator, according to the previous embodiment of the present invention, include piezoelectric ceramic powder having a composition of (1−x)Pb(Zr_{(1-y)}Ti_{y})O₃-xPb(Ni_{1/3}Nb_{2/3})O₃, where, x ranges from 0.25 to 0.4 and y ranges from 0.4 to 0.7, and can be fired at low temperature.

Accordingly, the electrode layer 20 may utilize not only Pd but also a low-temperature electrode material containing Pd in small amount.

The low-temperature electrode material means an electrode material that is known to be inadequate for a high-temperature co-firing process. In detail, the low-temperature electrode material, when being co-fired together with a piezoelectric body at high temperature, may fail to maintain the properties required for an electrode material in a sintered body, in particular, conductivity, or may result in the deterioration of the overall characteristics of the sintered body. However, according to the exemplary embodiment of the present invention, a low-temperature electrode material may be utilized. The low-temperature electrode material, although not limited thereto, may utilize a metal such as silver, copper or aluminum. Preferably, electrode layers may be formed of silver.

Alternatively, an alloy of the low-temperature electrode material and Pd may be used. In this case, the alloy may contain Pd at 10% or lower.

The piezoelectric actuator, according to this exemplary embodiment of the invention, may be manufactured by the following processes: making a piezoelectric layer by using the aforementioned ceramic composition for a piezoelectric actuator, forming an electrode layer on at least one of the top and bottom surfaces of the piezoelectric layer to prepare a stack, and performing co-firing upon the stack at low temperature.

The co-firing may be performed at a temperature of 950° C. or lower, preferably, 900° C. or lower.

The co-firing, performed at a temperature of 950° C. or lower, allows for the use of the low-temperature electrode material. According to the exemplary embodiment of the present invention, the low-temperature electrode material does not adversely affect the conductivity of an electrode layer and the piezoelectric properties of a sintered body.

Hereinafter, the present invention will be described in more detail with reference to the following inventive example, but the inventive example does not limit the scope of the present invention.

Raw powder of PbO, ZrO₂, TiO₂, NiO, and Nb₂O₅ was weighed so as to have a composition described below, and then subjected to a wet ball-milling process using ethanol or distilled water for 12 hours. At this time, ZrO₂ and TiO₂ were weighed to have a composition as described in table 1 below.

Thereafter, a drying process was performed thereon and a resultant material was then placed in a furnace and subjected to a calcining heat treatment at 850° C. for 4 hours, thereby synthesizing a PZT-PNN composition.

ZnO and CuO powder was added to and mixed with the completed PZT-PNN piezoelectric ceramic powder to have the ratio shown in the following formula. In this experiment, a ball-milling process was performed for 24 hours as this mixing process.

0.65[Pb (Zr_{(1-y)}Ti_{y})O₃]-0.35[Pb(Ni_{1/3}Nb_{2/3})O₃]+3 mol % ZnO+1 mol % CuO

Thereafter, drying was performed to obtain powder. The dried powder was compressed and then sintered through a heat treatment, thereby manufacturing a sample. The sintering was performed at a temperature ranging from 900° C. to 950° C. for 2 hours. The complete sample had a disc form having a diameter of 12.5 mm and a thickness of 0.88 mm. An electrode material was applied to the top and bottom surfaces of the disc-shaped sample and subjected to poling at a voltage of 4 kV/mm.

The piezoelectric properties of the manufactured sample were measured. Table 1 below and FIG. 2 show the measured piezoelectric properties.

The equipment used to measure the piezoelectric properties consisted of a d₃₃ meter (Micro-Epsilon Channel Product DT-3300, Raleigh, N.C.) and an impedance analyzer (Agilent Technologies HP 4294A, Santa Clara, Calif.).

TABLE 1

| | Relative | | | Dielectric | |
|---|---|---|---|---|---|
| y(Ti ratio) | density (%) | d33(pC/N) | kₚ | constant | Qₘ |
| 0.560 | 95.5 | 565 | 58.0 | 2480 | 60 |
| 0.565 | 97.5 | 550 | 58.5 | 2756 | 58 |
| 0.570 | 96.0 | 610 | 61.0 | 3725 | 54 |
| 0.575 | 95.0 | 555 | 57.0 | 3856 | 55 |
| 0.580 | 95.0 | 520 | 56.0 | 3506 | 67 |
| 0.585 | 92.0 | 505 | 54.5 | 3180 | 65 |
| 0.595 | 98.0 | 450 | 55.5 | 3270 | 61 |
| 0.600 | 97.0 | 450 | 55.5 | 3056 | 75 |
| 0.605 | 97.5 | 400 | 53.0 | 2730 | 79 |

The easiest way to confirm whether or not a piezoelectric material is fired appropriately is to measure the density thereof after a firing process. In general, a PZT-based material may have a desired firing density at around 1000° C.

However, according to an exemplary embodiment of the invention, it can be seen from Table 1 and FIG. 2 that the ceramic composition for a piezoelectric actuator, after being fired at 900° C., exhibits excellent piezoelectric properties and performance. The results of the firing at 900° C. are not considerably different from those of firing at 950° C.

That is, according to this exemplary embodiment, the ceramic composition for a piezoelectric actuator allows for the production of a piezoelectric material that can be fired at a low temperature of 950° C. or lower and has superior properties including a piezoelectric constant of 600 and mechanical coupling coefficient of 65%.

In the case in which such a piezoelectric material having a low firing temperature is used for an actual piezoelectric component, an inner electrode material consisting of 100-percent silver (Ag) or both Ag and Pd which is added in an amount of 10% is sufficient to realize desired properties.

As set forth above, according to exemplary embodiments of the invention, a ceramic composition for a piezoelectric actuator, allowing for low-temperature firing, can be provided by using PZT-PNN ceramic powder having a specific composition

A piezoelectric actuator can be manufactured by using the ceramic composition for a piezoelectric actuator piezoelectric actuator, and the piezoelectric actuator may utilize an economical electrode material.

Accordingly, the piezoelectric actuator can be manufactured with considerably reduced costs and have superior piezoelectric properties even after low-temperature firing. Thus, the piezoelectric actuator is applicable to a variety of products.

While the present invention has been shown and described in connection with the exemplary embodiments, it will be apparent to those skilled in the art that modifications and variations can be made without departing from the spirit and scope of the invention as defined by the appended claims.

What is claimed is:

1. A ceramic composition for a piezoelectric actuator, the ceramic composition, comprising piezoelectric ceramic powder expressed by a chemical formula, (1−x)Pb(Zr_{(1-y)}Ti_{y})O₃-xPb(Ni_{1/3}Nb_{2/3})O₃, where, x ranges from 0.25 to 0.4, and y ranges from 0.4 to 0.7.

2. The ceramic composition of claim 1, further comprising at least one additive selected from the group consisting of ZnO and CuO.

3. The ceramic composition of claim 2, wherein the additive is added in an amount of from 0.5 mol % to 10 mol %.

4. A method of manufacturing a ceramic composition for a piezoelectric actuator, the method comprising:
preparing a ceramic mixture by weighing raw powder so as to have a composition of (1−x)Pb(Zr_{(1-y)}Ti_{y})O₃-xPb(Ni_{1/3}Nb_{2/3})O₃, where x ranges from 0.25 to 0.4, and y ranges from 0.4 to 0.7; and
calcining the ceramic mixture to produce piezoelectric ceramic powder having a composition of (1−x)Pb(Zr_{(1-y)}Ti_{y})O₃-xPb(Ni_{1/3}Nb_{2/3})O₃, where x ranges from 0.25 to 0.4, and y ranges from 0.4 to 0.7.

5. The method of claim 4, wherein the raw powder comprises PbO, ZrO, TiO₂, NiO and Nb₂O₅.

6. The method of claim 4, further comprising mixing at least one additive selected from the group consisting of ZnO and CuO after the manufacturing of the piezoelectric ceramic powder.

7. The method of claim 6, wherein the additive is added in an amount of from 0.5 mol % to 10 mol %.

8. A piezoelectric actuator comprising:
at least one piezoelectric layer including a ceramic composition including piezoelectric ceramic powder having a composition of (1−x)Pb(Zr_{(1-y)}Ti_{y})O₃-xPb(Ni_{1/3}Nb_{2/3})O₃, where x 0.25 to 0.4, and y ranges from 0.4 to 0.7; and
an electrode layer formed on at least one of top and bottom surfaces of the piezoelectric layer.

9. The piezoelectric actuator of claim 8, wherein the piezoelectric layer includes at least one additive selected from the group consisting of ZnO and CuO.

10. The piezoelectric actuator of claim 8, wherein the electrode layer includes at least one metal selected from the group consisting of silver, copper and aluminum.

11. A method of manufacturing a piezoelectric actuator, the method comprising:
preparing a ceramic mixture by weighing raw powder so as to have a composition of (1−x)Pb(Zr_{(1-y)}Ti_{y})O₃-xPb(Ni_{1/3}Nb_{2/3})O₃, where x ranges from 0.25 to 0.4, and y ranges from 0.4 to 0.7;
calcining the ceramic mixture to produce piezoelectric ceramic powder having a composition of (1−x)Pb(Zr_{(1-y)}Ti_{y})O₃-xPb(Ni_{1/3}Nb_{2/3})O₃, where x ranges from 0.25 to 0.4, and y ranges from 0.4 to 0.7;
forming a piezoelectric layer using a ceramic composition including the piezoelectric ceramic powder;
forming a stack by forming an electrode layer on at least one of top and bottom surfaces of the piezoelectric layer; and
firing the stack at a temperature of 950° C. or less.

12. The method of claim 11, wherein the raw powder comprises PbO, ZrO, TiO₂, NiO and Nb₂O₅.

13. The method of claim 11, wherein the ceramic composition is mixed with at least one additive selected from the group consisting of ZnO and CuO.

14. The method of claim 11, wherein the electrode layer is formed of at least one metal selected from the group consisting of silver, copper and aluminum.
